(19) United States
(12) Patent Application Publication
(10) Pub. No.: US 2007/0248175 A1
(43) Pub. Date: Oct. 25, 2007

(54) Method for Generating Preamble Structures and Signaling Structures in a Mimo Ofdm Transmission System

(75) Inventors: Karsten Bruninghaus, Salzgitter (DE); Sebastian Obermanns, Bocholf (DE)

Correspondence Address: BELL, BOYD & LLOYD, LLP, P.O. BOX 1135, CHICAGO, IL, 60690, US

(73) Assignee: Siemens Aktiengesellschaft, Muenchen (DE)

(21) Appl. No.: 11/573,624

(22) PCT Filed: Jul. 27, 2005
(86) PCT No.: PCT/EP05/53658

§ 371 Date: Apr. 19, 2007

(30) Foreign Application Priority Data
Aug. 10, 2004 (DE) 10 2004 038 834.2

(51) Int. Cl. H03D 3/24

(52) U.S. Cl. 375/260

(57) ABSTRACT

The disclosure relates to a method for generating preamble structures and signaling structures for a data signal in a MIMO-OFDM transmission system with a multitude of antennas. To this end, the preamble structure has, for each antenna, a synchronization section with a predetermined synchronization sequence and has a channel estimation section with a predetermined channel estimation sequence. The synchronization sequences fulfill equations (I) and (II). Alternatively, the channel estimation sequence can fulfill equation (III). This makes it possible to realize efficient and downlink compatible MIMO transmission systems.

### FIELD OF TECHNOLOGY

The present disclosure relates to methods for generating preamble structures and signaling structures for OFDM transmission systems with a multitude of antennas, which can be used in high transmission rate WLANs (Wireless Local Area Network) also in mobile radio systems with multi-antenna technology.

### BACKGROUND

The usual aim of transmitting a known or at least partly known preamble is to make rapid synchronization and channel estimation possible for the recipient, so that the subsequent data can be evaluated with the greatest possible freedom from errors (i.e. in the ideal case only degraded by the input noise and/or interference). In connection with synchronization a distinction can be made between clock synchronization, frequency synchronization and symbol synchronization. Whereas clock synchronization relates to a synchronization of the D/A and A/D converter clocks in the transmitter and receiver, frequency synchronization relates to a synchronization of the mixer frequencies. In an OFDM transmission system with guard interval, such as that considered herein, a symbol synchronization is additionally required, of which the task is to position the evaluation window for the data symbols transmitted (in the frequency multiplex) so that no (channel impulse response shorter than the duration of the guard interval) or the least possible (channel impulse response longer than the duration of the guard interval) intersymbol interference occurs.

Conventional wireless OFDM transmission systems are used, for example, in WLANs (Wireless Local Area Networks) usually use only one antenna in the transmitter and/or receiver.

By contrast MIMO-OFDM transmission systems (MIMO, Multiple Input Multiple Output) represent an innovative expansion which—depending on the channel characteristics—make possible a considerable increase in spectral efficiency by using spatial multiplexing.

In this case the preamble must not only support the estimation of a single channel in the receiver, but it must be possible to determine the channel characteristics for each spatially multiplexed data stream in the receiver on the basis of the preamble.

Also, the task of the signaling is to inform the receiver about the physical transmission parameters, such as modulation and coding used in the transmitter for example.

### SUMMARY

Under an exemplary embodiment, a method is disclosed for generating preamble structures and signaling structures for packet-oriented data transmission based on the MIMO-OFDM transmission technology, so that, with relatively low processing overhead in the receiver, good facilities are provided for accurately estimating the synchronization and channel parameters for existing OFDM transmission systems (especially IEEE 802.11a, 802.11g).

By using a synchronization sequence in the synchronization section of the relevant antennas in accordance with
sₘ(n)=DFT⁻¹{Sₘ(k)} where Sₘ(k)=S(k)·e^{jφ}^{_{k,m}} (n−1, . . . , N),
all addressed receivers can evaluate both the signaling field and also the payload data field, even if no detailed a-priori information is available about the channel in the receiver. If for the synchronization sequence for the relevant antennas the equation
sₘ(n)=DFT⁻¹{Sₘ(k)}
with

$${S}_{m} ( k ) = {\sum }_{d = 1}^{{D}_{k}} {p}_{k , m , d} \cdot S ( k ) \cdot {ⅇ}^{{jφ}_{k , m , d} } ( n = 1 , … , N )$$

is used, the addressed receivers are again in a position to evaluate both the signaling field and also the payload data field, but in this case however detailed a-priori information about the channel is available in the transmitter. The addressed receivers can in this case represent MIMO receivers with a plurality of receive antennas but also receivers with only one receive antenna, which makes possible high-quality backwards compatibility with existing transmission systems.

Alternately the channel estimation sequence cm(n) for the relevant antennas can a concatenation of the OFDM symbols cm,x in accordance with
c_{m,x}(n)=DFT⁻¹{C_{m,x}(k)} and C_{m,x}(k)=p_{k,m,x}·C(k) (n=1, . . . , N)

which in the same or similar manner allows a signaling field and also a payload data field to be evaluated for all addressed receivers and makes backwards compatibility to conventional transmission systems possible.

Naturally these two alternatives can be also combined with one another as regards the embodiment of the synchronization sequences and the channel estimation sequences, which improves the reliability of the overall system.

The synchronization sequence sm(n) can either be prefixed by a typical OFDM guard interval or a guard interval with an inverted leading sign, with the synchronization sequence repeating at least once periodically.

Furthermore, to implement a specific transmit diversity method the correlation of the phase values in accordance with the equation

$$E \{ {ⅇ}^{{jφ}_{k , m}} \cdot {ⅇ}^{- {jφ}_{k + Δ k , m + Δ m}} \} \to \{ \begin{matrix}1 & for Δ k = 0 ⋀ Δ m = 0 \\ 0 & else\end{matrix}$$

can be as small as possible which means that all stations of the transmission system are able to evaluate the complete transmitted data packet, i.e. signaling field and payload data field, to obtain general information about the network and about reserved time domains.

Preferably this transmit diversity method is optimized by a specific form of implementation in accordance with

$${φ}_{k , m} = \frac{2 π k ( m - 1 )}{{M}_{T}}$$

which allows what is referred to as a Cyclic Delay Diversity (CCD) method to be implemented. From the implementation standpoint this method is advantageous because, by contrast with the general approach, only a single inverse Fourier transformation is required for each OFDM symbol in the transmitter.

To use the proposed method on the WLAN according to the IEEE 802.11 standard, a basic synchronization signal in accordance with

$$\begin{matrix}{S ( k )}_{- 26 : 26} = \sqrt{\frac{13}{6}} \{ 0 , 0 , 1 + j , 0 , 0 , 0 , - 1 - j , 0 , 0 , 0 , 1 + \\ j , 0 , 0 , 0 , - 1 - j , 0 , 0 , 0 , - 1 - j , 0 , 0 , 0 , 1 + \\ j , 0 , 0 , 0 , 0 , 0 , 0 , 0 , - 1 - j , 0 , 0 , 0 , - 1 - \\ j , 0 , 0 , 0 , 1 + j , 0 , 0 , 0 , 1 + j , 0 , 0 , 0 , 1 + \\ j , 0 , 0 , 0 , 1 + j , 0 , 0 \}\end{matrix}$$

and a basic channel estimation signal in accordance with

$$\begin{matrix}{C ( k )}_{- 26 : 26} = \{ 1 , 1 , - 1 , - 1 , 1 , 1 , - 1 , 1 , - 1 , 1 , 1 , 1 , 1 , 1 , 1 , - \\ 1 , - 1 , 1 , 1 , - 1 , 1 , - 1 , 1 , 1 , 1 , 1 , 0 , 1 , - 1 , - 1 , 1 , 1 , - \\ 1 , 1 , - 1 , 1 , - 1 , - 1 , - 1 , - 1 , - 1 , 1 , 1 , - 1 , - 1 , 1 , - \\ 1 , 1 , - 1 , 1 , 1 , 1 , 1 \}\end{matrix}$$

are used, which makes a direct implementation in such existing systems possible.

With regard to the channel estimation sequence, this can also be formed for the relevant antenna from a concatenation of the OFDM symbols cm,x(n) in accordance with

$$\begin{matrix}{c}_{m} ( n ) = {g}_{m , 1} ( n ) \underbrace{{c}_{m , 1} ( n ) … {c}_{m , 1} ( n )}_{j} {g}_{m , 2} ( n ) \underbrace{{c}_{m , 2} ( n ) … {c}_{m , 2} ( n )}_{j} … \\ {g}_{m , D} ( n ) \underbrace{{c}_{m , D} ( n ) … {c}_{m , D} ( n )}_{j} ,\end{matrix}$$

with j representing the number of repetitions of the OFDM symbols cm,x(n).

In respect of the guard intervals used, these can be formed from the single typical OFDM guard interval sequence
g_{m,x}(n)=c_{m,x}(n+N−N_{G}) n=1, . . . , N_{G}

or from the double typical OFDM guard interval sequence
g_{m,x}(n)=c_{m,x}(n+N−2N_{G}) n=1, . . . , 2N_{G},

with NG representing the number of samples of the guard interval.

Furthermore a signaling section can be arranged in the time area between a payload data structure and the channel estimation section of the preamble structure, with the signaling section containing a signaling sequence for the relevant antenna, which is formed from a concatenation of the OFDM symbols am,x(n) according to
aₘ(n)=g_{m,1}(n)a_{m,1}(n)g_{m,2}(n)a_{m,2}(n) . . . g_{m,V}(n)a_{m,V}(n)
with

$$\begin{matrix}{a}_{m , x} ( n ) = {DFT}^{- 1} \{ {A}_{m , x} ( k ) \} und {A}_{m , x} ( k ) = {I}_{x}^{sig} ( k ) \cdot \\ {\sum }_{d = 1}^{{D}_{k}} {p}_{k , m , d} n = 1 , … , N\end{matrix}$$

as well as the typical OFDM guard interval sequence
g_{m,x}(n)=a_{m,x}(n+N−N_{G}) n=1, . . . , N_{G}.

Alternately the channel estimation section with a channel estimation sequence cm(n) can be subdivided into a first part channel estimation section and a second part channel estimation section with the part channel estimation sequences cm1(n) and also cm2(n) and the signaling section can be subdivided into a first part signaling section and a second part signaling section with the part signaling sequences am1(n) as well as am2(n) and can be regenerated in the chronological sequence first part channel estimation section, first part signaling section, second part channel estimation section and second part signaling section, with the first and the second channel estimation sequence being formed either in accordance with
cₘ¹(n)=g_{m,1}(n)c_{m,1}(n)
cₘ²(n)=g_{m,2}(n)c_{m,2}(n) . . . g_{m,D}(n)c_{m,D}(n)

or in accordance with

$${c}_{m}^{1} ( n ) = {g}_{m , 1} ( n ) \underbrace{{c}_{m , 1} ( n ) … {c}_{m , 1} ( n )}_{j}$$

$${c}_{m}^{2} ( n ) = {g}_{m , 2} ( n ) \underbrace{{c}_{m , 2} ( n ) … {c}_{m , 2} ( n )}_{j} … {g}_{m , D} ( n ) \underbrace{{c}_{m , D} ( n ) … {c}_{m , D} ( n )}_{j}$$

using a single or double typical OFDM guard interval, and with the first part signaling sequence being formed in accordance with
aₘ¹(n)=g_{m,1}(n)a_{m,1}(n)g_{m,2}(n)a_{m,2}(n) . . . g_{m,V′}(n)a_{m,V′}(n)
and the second part signaling sequence being formed in accordance with
aₘ²(n)=g_{m,V′+1}(n)a_{m,V′+1}(n)g_{m,V′+2}(n)a_{m,2}(n) . . . g_{m,V}(n)a_{m,V}(n)
with

$$\begin{matrix}{a}_{m , x} ( n ) = {DFT}^{- 1} \{ {A}_{m , x} ( k ) \} and {A}_{m , x} ( k ) \\ = \{ \begin{matrix}{I}_{x}^{sig} ( k ) \cdot {p}_{k , m , 1} & for 1 \leq x \leq {V}^{′} \\ {I}_{x}^{sig} ( k ) \cdot {\sum }_{d = 1}^{{D}_{k}} {p}_{k , m , d} & for {V}^{′} < x \leq V\end{matrix}\end{matrix}$$

as well as the typical OFDM guard interval sequence
g_{m,x}(n)=a_{m,x}(n+N−N_{G}) n=1, . . . , N_{G}.
In this case backwards compatibility is again made possible since stations in a conventional transmission system can now also evaluate the signaling field, which means that the number of the following channel estimate sequences is known a-priori.

Preferably the column vectors Pk,x, x=1, . . . , Dk, of the matrix Pk are sorted so that the variance of the power values

$${P}_{x} = {\sum }_{∀ k} {\sum }_{m = 1}^{{M}_{T}} {\vert {p}_{k , m , x} \vert}^{2} x = 1 , … , D$$

taking into account the relationship pk,m,x=0 for x>Dk is as small as possible. For each subcarrier k in this case the column vectors Pk,x, with x=1, . . . , Dk, of the spatial equalization matrix Pk are sorted in a first step in accordance with size so that

$${\sum }_{m = 1}^{{M}_{T}} {\vert {p}_{k , m , x} \vert}^{2} \geq {\sum }_{m = 1}^{{M}_{T}} {\vert {p}_{k , m , z} \vert}^{2} \qquad for \qquad z > x$$

is fulfilled, and in a second step are subjected to a random permutation according to specification P_{k,x}→P_{k,(x+k)modD}_{ₖ}.

### BRIEF DESCRIPTION OF THE DRAWINGS

The present disclosure also relates to data processing system. The data processing system is especially suitable for the executing the method as claimed in the invention or one of its developments, so that the technical effects specified above also apply to the data processing system.

FIG. 1 illustrates a simplified diagram in the time domain for transmitting data according to the IEEE 802.11 standard;

FIG. 2 illustrates a simplified diagram of a preamble structure in accordance with the IEEE 802.11 standard;

FIG. 3 illustrates a simplified diagram in the time domain of the signaling structure in accordance with IEEE 802.11;

FIG. 4 illustrates a simplified table to illustrate the meaning of the individual bits in accordance with FIG. 3;

FIG. 5 illustrates a preamble structure and signaling structure according to a first exemplary embodiment; and

FIG. 6 illustrates a preamble structure and signaling structure according to a second exemplary embodiment.

### DETAILED DESCRIPTION

An exemplary WLAN (Wireless Local Area Network) transmission systems is described below according to a IEEE 802.11 standard as an OFDM transmission system, with alternate OFDM transmission systems also being conceivable. According to the IEEE 802.11 standard, to which explicit reference is made at this point, OFDM symbols are used in an OFDM (Orthogonal Frequency Division Multiplexing) transmission system. Such a multiplex method is especially suitable for terrestrial transmissions of digital radio signals subject to heavy interference, since it is insensitive to echoes.

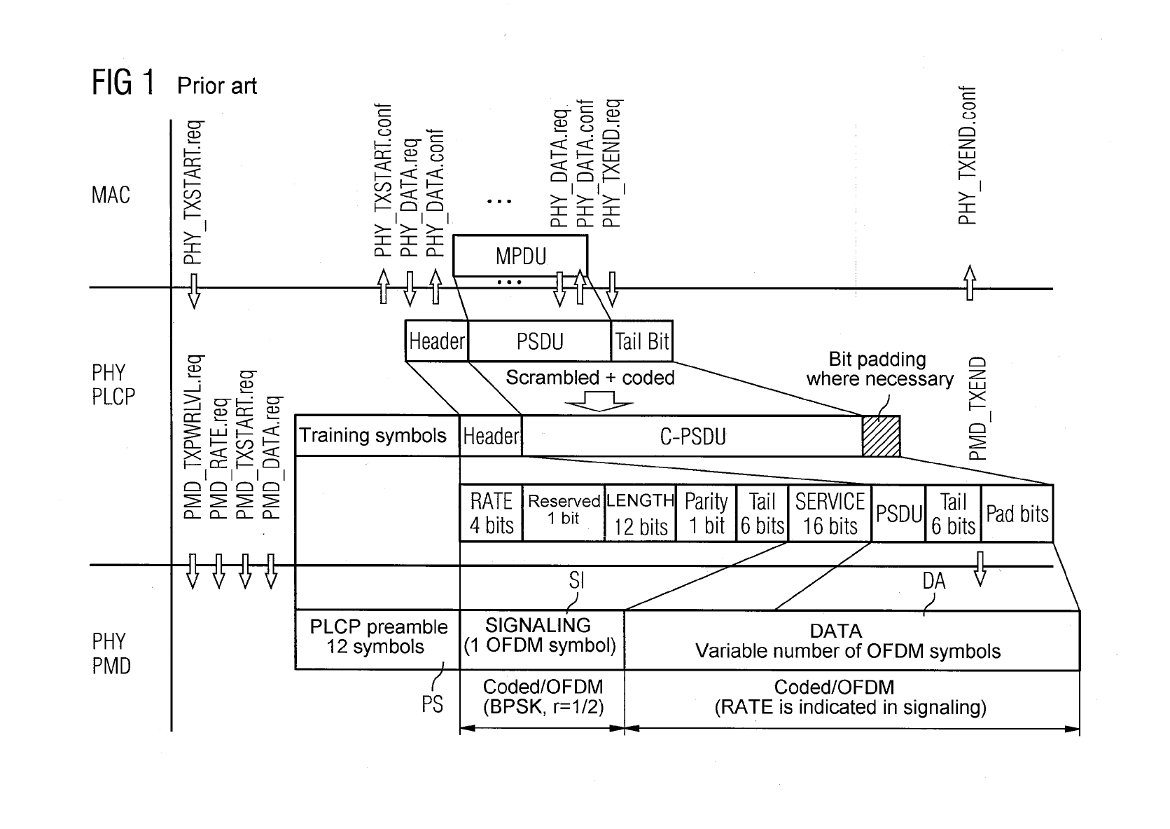

Thus, as a preparatory step, a rough overview of the data packets in the Physical Layer (PHY) and in the Medium Access Control (MAC) in accordance with FIG. 1 is first described, as can be found in IEEE 802.11. For a more detailed description the reader is referred to this Standard.

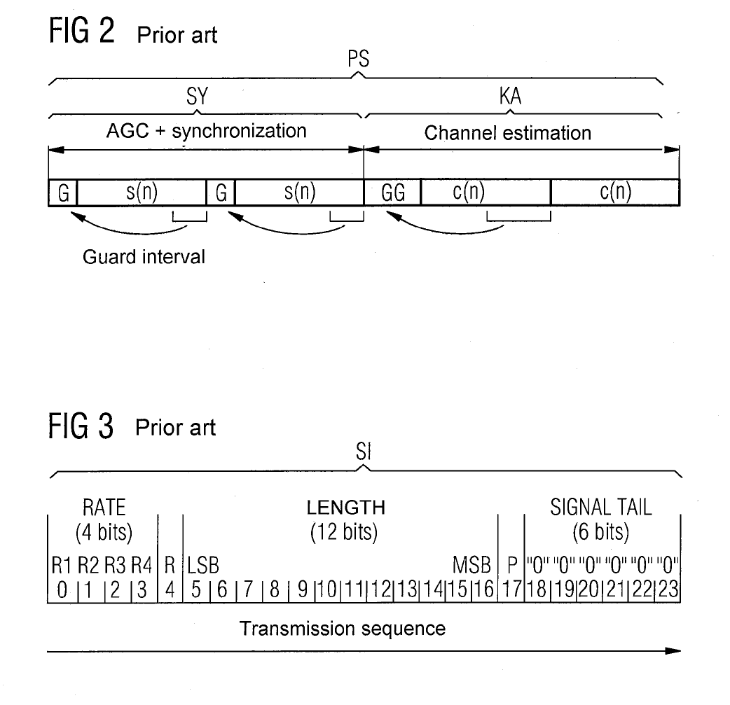

According to FIG. 1, MAC designates the Medium Access Control and PHY the physical layer. The physical layer is further subdivided into a convergence procedure PLCP (Physical Layer Convergence Procedure) and what is referred to as the PMD (Physical Medium Dependent). The abbreviation MPDU refers to the MAC Protocol Data Unit, while PSDU represents the corresponding PLCP Service Data Unit. Essentially, to implement a power matching or “Automatic Gain Control” AGC, of a synchronization and of a channel estimation, the data sequence has training symbols in the form of what is known as a PLCP preamble, which will be referred to below as a preamble structure PS and which is shown in FIG. 2 in simplified form.

In the WLAN, the preamble structure PS may include twelve OFDM symbols, followed by a signaling field or a signaling structure with a signaling section SI (an OFDM symbol). The signaling section SI in accordance with the WLAN standard is shown in simplified form in FIG. 3, in which case it also represents part of a header. Following the signaling field or the signaling section SI is the actual payload data field DA, in which a variable number of OFDM symbols are stored and which contains the above-mentioned PLCP Service Data Unit.

For the transmission of data, a command “PHY_TXSTART.request” is sent on the MAC side, which puts the physical layer PHY into the transmission state. The convergence procedure of the physical layer PLCP then sends a plurality of commands to the transmission-medium-dependent layer PMD, which causes the preamble structure PS and the signaling section SI to be transmitted. As soon as the transmission of the preamble structure PS begins, the encryption or scrambling and coding of the actual data is undertaken. The scrambled and coded data is subsequently exchanged between the Medium Access Control MAC and the convergence procedure of the physical layer PLCP by a plurality of data exchange commands “PHY_DATA.req” and “PHY_DATA.conf”. The data transmission or the transmission of the data packet is concluded when the physical layer PHY has assumed the receive state, with each command “PHY_TXEND.request” being confirmed by a command “PHY_TXEND.confirm” by the physical layer.

Consequently a data packet on the physical layer PHY may include three parts. Initially, a preamble structure PS for parameter estimation, i.e. an automatic gain control AGC, a frequency and OFDM symbol synchronization, as well as a channel estimation. This preamble structure PS follows the signaling structure or the signaling section SI, with which the signaling of the operating mode of the physical layer used (coding rate, modulation) as well as the length of the data packets is defined. Finally the actual payload data is located in the actual data field DA, consisting of a variable number of OFDM symbols. Its data rate is already indicated in signaling field SI.

FIG. 2 shows a more detailed diagram of the preamble structure PS in accordance with FIG. 1, with the same reference symbols indicating the corresponding signal sequences and such sequences thus not being described again.

In accordance with FIG. 2 the preamble structure PS includes four OFDM symbols, of which two are provided for the automatic gain control AGC as well as a course synchronization and two OFDM symbols are provided for a channel estimation as well as fine synchronization.

G in this diagram indicates a guard interval with a guard interval sequence, with GG being a double guard interval, i.e. a guard interval of double duration. The sample values s(n) designate a synchronization sequence, i.e. the signal sequence for supporting the synchronization in the receiver. This synchronization sequence is produced by the inverse Fourier transformation of

$$\begin{matrix}{S ( k )}_{- 26 \text{:} 26} = \sqrt{\frac{13}{6}} \{ 0 , 0 , 1 + j , 0 , 0 , 0 , - 1 - j , 0 , 0 , 0 , 1 + \\ j , 0 , 0 , 0 , - 1 - j , 0 , 0 , 0 , - 1 - j , 0 , 0 , 0 , 1 + \\ j , 0 , 0 , 0 , 0 , 0 , 0 , 0 , - 1 - j , 0 , 0 , 0 , - \\ 1 - j , 0 , 0 , 0 , 1 + j , 0 , 0 , 0 , 1 + \\ j , 0 , 0 , 0 , 1 + j , 0 , 0 , 0 , 1 + j , 0 , 0 \}\end{matrix}$$

In a similar fashion c(n) designates a channel estimation sequence, i.e. a signal sequence for supporting the channel estimation in the receiver, which is again produced from the inverse Fourier transformation of

$$\begin{matrix}{C ( k )}_{- 26 \text{:} 26} = \{ 1 , 1 , - 1 , - 1 , 1 , 1 , - 1 , 1 , - 1 , 1 , 1 , 1 , 1 , 1 , 1 , \\ - 1 , - 1 , 1 , 1 , - 1 , 1 , - 1 , 1 , 1 , 1 , 1 , 0 , 1 , \\ - 1 , - 1 , 1 , 1 , - 1 , 1 , - 1 , 1 , - 1 , - 1 , - 1 , - 1 , \\ - 1 , 1 , 1 , - 1 , - 1 , 1 , - 1 , 1 , - 1 , 1 , 1 , 1 , 1 \} .\end{matrix}$$

S(k) in this case designates a basic synchronization sequence signal in the frequency range and C(k) a basic channel estimation signal in the frequency range, as is defined for WLAN explicitly in the IEEE 802.11 Standard.

FIG. 3 shows a simplified diagram for illustrating the signaling structure in accordance with FIG. 1, with the same reference symbols indicating the corresponding signal sequences and such sequences thus not being described again.

The sampling sequence of the corresponding signaling OFDM symbol again results from the inverse Fourier transformation of the bit sequence shown in FIG. 3. This bit sequence consequently contains a data field with four bits R1 to R4 for defining a data rate RATE, a data field with a reserved bit R, a data field LENGTH to define a data length with the bits R5 through R16, a parity bit P and a signaling tail SIGNAL TAIL with six bits for decoding the fields for the data rate RATE and the data length LENGTH directly after receipt of the tail bits.

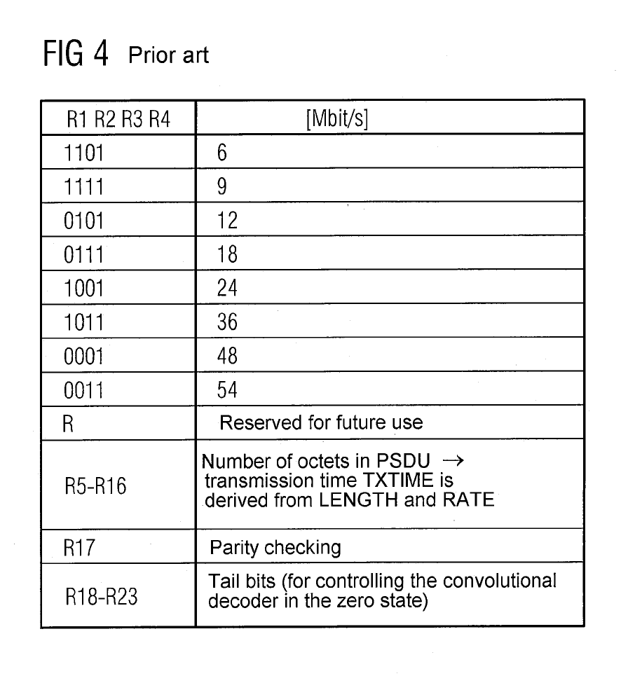

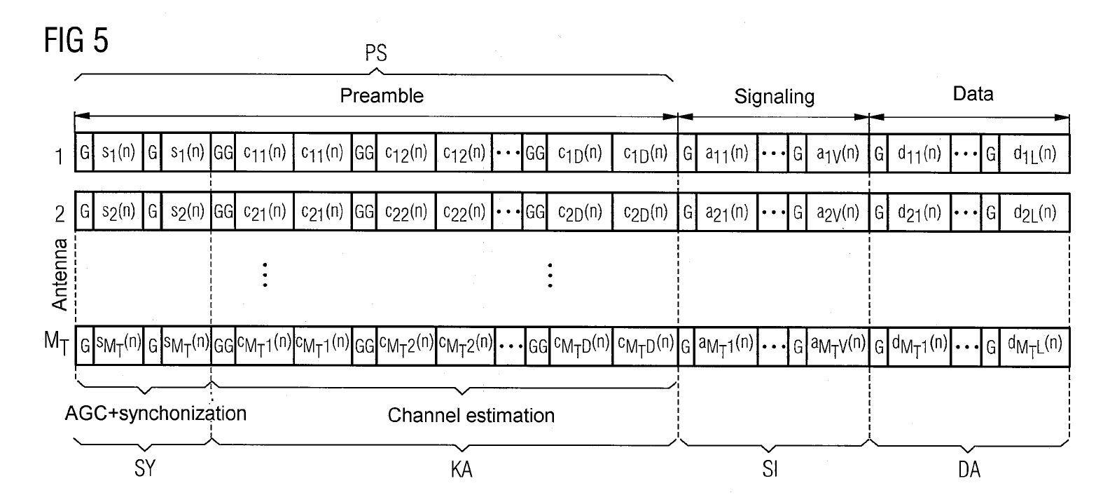

The meaning of the individual bits R1 through R23 is shown in the table in accordance with FIG. 4. The data packet is transmitted in this case using the operating mode for the physical layer (PHY mode) of the rate specified in the RATE field.

In accordance with the present disclosure, such an OFDM transmission system is now to be applied to a MIMO OFDM transmission system with a plurality of antennas in relevant transmitters and receivers, whereby, as regards the definition of suitable preamble and signaling structures, the following three cases can be distinguished.

In accordance with a first case, all stations, i.e. MIMO (Multiple Input Multiple Output) stations and SISO (Single Input Single Output) stations must be able to evaluate the complete sent data packet, i.e. signaling field and data field, to obtain all information about the network and about reserved timing areas. This relates especially to the frames “Beacon”, RTS (Request To Send), CTS (Clear To Send), CTS-self and CF-end (Contention Free).

In a second case all stations must be in a position to be able to evaluate at least the signaling field SI.

In a third case only the addressed receiver must be in a position to be able to evaluate the signaling field and the data field.

These considerations for implementing a MIMO-OFDM transmission system are discussed more below. In the second case, however, the end of a data packet can be precisely predicted on the basis of the “RATE” and “LENGTH” field. Collisions are avoided by Carrier Sense Multiple Access with Collision Avoidance (CSMA/CA) provided in any event by the transmission system, but even without any knowledge of these parameters. Even if the parity check provides an incorrect result, with the presence of a valid signaling field being indicated although it is actually not present, and thereby a start being made on evaluating the data part which does not exist in the known form, the PLCP receive method presented in IEEE 802.11 avoids any negative effects on the currently active data transmission between corresponding devices.

A precondition for the subsequent considerations of cases 1 through 3 is therefore that the MIMO signal processing applied in the transmitter to each subcarrier k can be described by a linear operation, so that after the OFDM or OFDM processing in the receiver the signal
[Rₖ]_{M}_{_{R}}ₓ₁=[Hₖ]_{M}_{_{R}}_{xM}_{_{T}}·[Pₖ]_{M}_{_{T}}_{xD}_{ₖ}·[Iₖ]_{D}_{ₖ}ₓ₁=[Gₖ]_{M}_{_{R}}_{xD}_{ₖ}·[Iₖ]_{D}_{ₖ}ₓ₁

is present. In this case Rk stands for the receive vector, Hk the channel matrix, Pk the MIMO preprocessing matrix and Ik the data vector. Any noise influences or other interference variables are ignored in this case. The subscripted indices alongside the pointed brackets identify the matrix dimensions, with the square brackets only being inserted to obtain a clear separation between the matrix indices and the matrix dimension indices.

Before the individual cases and the associated preamble and signaling structures are described below, a definition of the abbreviations used will first be provided:

G: Guard interval

GG: Guard interval double length (=double guard interval)

DFT: Discrete Fourier-Transformation

DFT-1: Inverse Discrete Fourier-Transformation

OFDM: Orthogonal Frequency Division Multiplexing

MT: Number of transmit antennas

n: Time index (=scan value)

x: Another time index (=OFDM symbol index)

m: Antenna index

d: Index of the spatial data stream

k: Subcarrier index (=frequency index; Requires: OFDM-based transmission system)

V′: Number of OFDM symbols required for transmission of part signaling information

V: Number of OFDM symbols required for transmission of complete signaling information

L: Number of OFDM symbols on which payload data is transmitted

N: Number of sample values per OFDM symbol (depending on the D/A or A/D converter rate)

Dk: Number of spatial data streams which are transmitted on the kth subcarrier

D: Maximum number of spatial data streams over all subcarriers,

$$D = {max}_{∀ k} {D}_{k}$$

φk,m: Pseudo-random (but known to the receiver) frequency (index k) and antenna-dependent (Index m) phase rotation (of the basic synchronization signal)

φk,m,d: Pseudo-random (but known to the receiver) frequency (index k) antenna-dependent (index m) and space-dependent (index d) phase rotation (of the basic synchronization signal)

$$\begin{matrix}{[ {P}_{k} ]}_{{M}_{T} {xD}_{k}} = ( {P}_{k , 1} , {P}_{k , 2} , … , {P}_{k , {D}_{k}} ) \\ = ( \begin{matrix}{p}_{k , 1 , 1} & {p}_{k , 1 , 2} & ⋯ & {p}_{k , 1 , {D}_{k}} \\ {p}_{k , 2 , 1} & {p}_{k , 1 , 2} & & {p}_{k , 1 , {D}_{k}} \\ ⋮ & & ⋰ & ⋮ \\ {p}_{k , {M}_{T} , 1} & {p}_{k , {M}_{T} , 2} & ⋯ & {p}_{k , {M}_{T} , {D}_{k}}\end{matrix} )\end{matrix}$$

: Matrix of the dimension MT×Dk used for spatial clipping of the payload data on the kth subcarrier

P_{k,d}: dth column vector of the matrix [Pₖ]_{M}_{_{T}}_{xD}_{ₖ}

pk,m,d: mth row and dth column element of the matrix [Pₖ]

sm(n): Synchronization sequence (=signal sequence for supporting synchronization in the receiver) which is transmitted via antenna m.

S(k): Basic synchronization signal in the frequency range

Sm(k): Synchronization signal in the frequency range which is transmitted via antenna m

cm,x(n): xth channel estimation sequence (=signal sequence for supporting the channel estimation in the receiver) which is transmitted via antenna m

C(k): Basic channel estimation signal in the frequency range

Cm,x(k): xth channel estimation signal in the frequency range, which is transmitted via antenna m

am,x(n): xth signaling sequence (=data sequence with signaling information regarding the transmission mode used) which is transmitted via antenna m

Am,x(k): xth signaling signal in the frequency range which is transmitted via antenna m

Iₓ^{sig}(k): Signaling information (contains information about coding and modulation of each individual spatial data stream for example, length of the data packet, . . . ), which is transmitted on the kth subcarrier of the xth OFDM signaling symbol.

dm,x(n): xth data sequence which is transmitted via antenna m

I_{d,x}(k): Information which is transmitted on the dth spatial data stream of the kth subcarrier of the xth OFDM payload data symbol.

Dm,x(k): xth data signal in the frequency range which is transmitted via antenna m

Note: What is referred to here as a “sequence” are the sample values as OFDM symbols, i.e. n=1, . . . , N

Case 1:

It is basically true to say that those data packets containing important information about reserved resources or network elements must be able to be evaluated not only by all stations of different types (i.e. MIMO or SISO stations), but must still also be able to be evaluated at maximum communication range, which is why it makes little sense here to use spatial multiplexing. By contrast only one data stream is transmitted here with the lowest possible data rate. If for example a MIMO transmitter is available, i.e. the transmitter has a number of antennas, the security of detection in the receiver can be increased by use of a transmit diversity method. In this case the restriction applies that the method used must for reasons of compatibility be transparent for all stations.

A transmit diversity method which meets this requirement is for example characterized by a preprocessing vector in the form
[Pₖ]_{M}_{_{T}}ₓ₁=(e^{jφ}^{_{k,1}},e^{jφ}^{_{k,2}}, . . . , e^{jφ}^{_{k,M}}_{_{T}})^{T}.

To put it more precisely, each subcarrier k is applied to each antenna m with a pseudo-random phase rotation φk,m. Without restricting the general applicability φk,1=0 can be set, so that the SISO one-antenna case 1 is retained unchanged as a special case. Without initially specifying a phase sequence in detail, a general requirement can be made that the correlation of the phase values is as small as possible. This corresponds to the relationship:

$$E \{ {ⅇ}^{{jφ}_{k , m}} \cdot {ⅇ}^{- {jφ}_{k + Δ k , m + Δ m}} \} \to \{ \begin{matrix}1 & for Δ k = 0 ⋀ Δ m = 0 \\ 0 & else\end{matrix} .$$

A specific basic implementation form of this proposed preprocessing is represented by the CDD method (Cyclic Delay Diversity) with

$${φ}_{k , m} = \frac{2 π k ( m - 1 )}{{M}_{T}} .$$

From the implementation standpoint the CDD method is advantageous, because, by contrast with the general approach, only a single inverse Fourier transformation per OFDM symbol (or per OFDM symbol) is required in the transmitter.

In accordance with this first case, MIMO stations are consequently used which are equipped with a number of antennas, which transmit data packets which are understood by all stations, i.e. both MIMO and also SISO stations. In this case a transmit diversity method in the form of a pseudo-random phase rotation is applied to each subcarrier and each antenna, with especially a CDD method being used. The phase vectors Pk used are identical in such case for all OFDM symbols including the preamble symbols S(k) and C(k). Otherwise the same PLCP transmit procedure is employed as that shown in FIG. 1 for example in accordance with IEEE 802.11. This method still makes sense even if no SISO devices are active, i.e. no compatibility requirements exist.

It should also be noted that the method described is only really transparent for SISO devices, if, in conjunction with the channel estimation in the receiver, filtering is performed exclusively in the time direction, i.e. averaging over the two c(n) sequence series, and no filtering is undertaken in the frequency direction.

FIG. 5 illustrates a simplified representation of a data packet with an inventive preamble structure and signaling structure in accordance with a first exemplary embodiment.

In accordance with FIG. 5, associated data packets are shown in one frequency range for the relevant antennas 1, 2, . . . MT, with the data packets for the individual antennas essentially corresponding to a data packet in accordance with FIGS. 1 through 4, provided a MIMO-OFDM transmission system in accordance with WLAN is to be implemented.

The preamble structures for the relevant antennas shown in FIG. 5 are consequently shown in the time domain and discrete.

Case 3:

When, in accordance with case 3, only the addressed MIMO receiver has to be in a position to actually be able to evaluate the data packet sent, the degree of freedom with regard to the design of the preamble structure PS as well as of the signaling structure SI used is at its maximum. The number D of the channel estimation sequence sequence pairs c(n) for channel estimation corresponds in this case to the maximum number of the data streams which are to be transmitted per subcarrier k, i.e. D=max{Dk}. The data on each subcarrier is transmitted using the matrices

$$\begin{matrix}{[ {P}_{k} ]}_{{M}_{T} {xD}_{k}} = ( {P}_{k , 1} , {P}_{k , 2} , … , {P}_{k , {D}_{k}} ) \\ = ( \begin{matrix}{p}_{k , 1 , 1} & {p}_{k , 1 , 2} & ⋯ & {p}_{k , 1 , {D}_{k}} \\ {p}_{k , 2 , 1} & {p}_{k , 1 , 2} & & {p}_{k , 1 , {D}_{k}} \\ ⋮ & & ⋰ & ⋮ \\ {p}_{k , {M}_{T} , 1} & {p}_{k , {M}_{T} , 2} & ⋯ & {p}_{k , {M}_{T} , {D}_{k}}\end{matrix} ) .\end{matrix}$$

As regards the preprocessing, in accordance with the invention the following processing is viewed as especially efficient:

For the synchronization sequences s(n) two different variants can be applied:

According to variant a) the synchronization sequences for the relevant antennas satisfy the relationship
sₘ(n)=DFT⁻¹{Sₘ(k)} with Sₘ(k)=S(k)·e^{jφ}^{_{k,m}} n=1, . . . , N,

so that where possible uncorrelated signals will be transmitted over the individual antennas. This variant a) is especially to be applied if there is no more detailed a-priori information available in the transmitter about the relevant channel.

In accordance with a variant b) the synchronization sequences for the relevant antennas will satisfy the equation

$${s}_{m} ( n ) = {DFT}^{- 1} \{ {S}_{m} ( k ) \} with$$

$$\begin{matrix}{S}_{m} ( k ) = {\sum }_{d = 1}^{{D}_{k}} {p}_{k , m , d} \cdot S ( k ) \cdot {ⅇ}^{{jφ}_{k , m , d}} & n = 1 , … , N\end{matrix} ,$$

with this variant b) especially being employed if there is more detailed a-priori information available in the transmitter about the relevant channel.

To adapt this method, to a WLAN transmission system for example, the equation

$$\begin{matrix}{S ( k )}_{- 26 \text{:} 26} = \sqrt{\frac{13}{6}} \{ 0 , 0 , 1 + j , 0 , 0 , 0 , - 1 - j , 0 , 0 , 0 , 1 + \\ j , 0 , 0 , 0 , - 1 - j , 0 , 0 , 0 , - 1 - j , 0 , 0 , 0 , 1 + \\ j , 0 , 0 , 0 , 0 , 0 , 0 , 0 , - 1 - j , 0 , 0 , 0 , - \\ 1 - j , 0 , 0 , 0 , 1 + j , 0 , 0 , 0 , 1 + \\ j , 0 , 0 , 0 , 1 + j , 0 , 0 , 0 , 1 + j , 0 , 0 \}\end{matrix}$$

is used for the basic transmission signal, as defined in the IEEE 802.11 Standard.

In accordance with FIG. 5 these synchronization sequences sm(n) can each be preceded by a typical OFDM guard interval G, with the synchronization sequence sm(n) being repeated at least once periodically. Alternately they can also be preceded by inverted leading sign guard intervals.

Alternately or in addition however the channel estimate sequences c(n) can be used for implementation as SISO-compatible MIMO transmission systems.

Consequently the channel estimate sequences for the relevant antennas 1 through MT in the respective channel estimation sections KA of the preamble structures PS in accordance with FIG. 5 can consist of a concatenation of the OFDM symbols cm,x(n) in accordance with
cₘ(n)=g_{m,1}(n)c_{m,1}(n)g_{m,2}(n)c_{m,2}(n) . . . g_{m,D}(n)c_{m,D}(n)

and the subsequent equation
c_{m,x}(n)=DFT⁻¹{C_{m,x}(k)} und C_{m,x}(k)=p_{k,m,x}·C(k) n=1, . . . , N

It is assumed in this case that the receiver can derive the number D of the channel estimation sequence pairs for channel estimation directly from the receive signal (for example by determining the autocorrelation function (AKF) spaced at 4 of 64 sample values over a time window of the same length), so that signaling of this parameter is not absolutely necessary.

In its turn, for adaptation to the WLAN transmission system described at the start, a basic channel estimation signal define in IEEE 802.11

$$\begin{matrix}{C ( k )}_{- 26 \text{:} 26} = \{ 1 , 1 , - 1 , - 1 , 1 , 1 , - 1 , 1 , - 1 , 1 , 1 , 1 , 1 , 1 , 1 , \\ - 1 , - 1 , 1 , 1 , - 1 , 1 , - 1 , 1 , 1 , 1 , 1 , 0 , 1 , \\ - 1 , - 1 , 1 , 1 , - 1 , 1 , - 1 , 1 , - 1 , - 1 , - 1 , - 1 , \\ - 1 , 1 , 1 , - 1 , - 1 , 1 , - 1 , 1 , - 1 , 1 , 1 , 1 , 1 \}\end{matrix}$$

can be used. If Dk<D . . . , then Pk,m,x does not exist in the range Dk<x≦D and is to be set to zero accordingly.

Once again the channel estimation sequence cm(n) can also be repeated at least one periodically. For example the channel estimation sequence cm(n) for the relevant antenna is formed from a concatenation of the OFDM symbols cm,x(n) according to

$$\begin{matrix}{c}_{m} ( n ) = {g}_{m , 1} ( n ) \underbrace{{c}_{m , 1} ( n ) … {c}_{m , 1} ( n )}_{j} {g}_{m , 2} ( n ) \underbrace{{c}_{m , 2} ( n ) … {c}_{m , 2} ( n )}_{j} … \\ {g}_{m , D} ( n ) \underbrace{{c}_{m , D} ( n ) … {c}_{m , D} ( n )}_{j} ,\end{matrix}$$

with j representing the number of repetitions of the OFDM symbols cm,x(n).

Although in accordance with FIG. 5 a guard interval GG is formed from the double typical OFDM guard interval sequence
g_{m,x}(n)=c_{m,x}(n+N−2N_{G}) n=1, . . . , 2N_{G}
for the channel estimation sequence, with NG representing the number of the sample values of the guard interval, the guard interval can also be formed from the single typical OFDM guard interval sequence
g_{m,x}(n)=c_{m,x}(n+N−N_{G}) n=1, . . . , N_{G}.

Further remarks about automatic gain control will be inserted at this point.

Normally the transmit power across all OFDM payload symbols (i.e. those symbols containing payload information) is constant, i.e.

$$\begin{matrix}{P}_{S , data , x} = E \{ \frac{1}{N} {\sum }_{n = 1}^{N} {\sum }_{m = 1}^{{M}_{T}} {\vert {d}_{m , x} ( n ) \vert}^{2} \} ∝ \\ E \{ {{\sum }^{}}_{∀ k} {\sum }_{m = 1}^{{M}_{T}} {{\sum }_{d = 1}}^{{D}_{k}} {\vert {p}_{k , m , d} \cdot {I}_{d , x} ( k ) \vert}^{2} \} \\ = {\sum }_{∀ k} {\sum }_{m = 1}^{{M}_{T}} {\sum }_{d = 1}^{{D}_{k}} {\vert {p}_{k , m , d} \vert}^{2} \cdot E \{ {\vert {I}_{d , x} ( k ) \vert}^{2} \} \\ = const f \ddot{u} r alle x \\ = 1 , … , L\end{matrix}$$

with E{} designating the expected value.

The transmit power of the channel estimation sequence amounts to:

$${P}_{S , est , x} = \frac{1}{N} {\sum }_{n = 1}^{N} {\sum }_{m = 1}^{{M}_{T}} {\vert {c}_{m , x} ( n ) \vert}^{2} ∝ {\sum }_{∀ k} {\sum }_{m = 1}^{{M}_{T}} {\vert {p}_{k , m , x} \vert}^{2} \cdot {\vert C ( k ) \vert}^{2}$$

$$x = 1 , … , D$$

This produces the following observation:

Both terms differ in general since the upper term still contains a summation of all spatial data streams. This difference is usually compensated for again by a weighting w known to the receiver of the basic channel estimate signal C(k), i.e. |C(k)|²=w·E{|I_{d,x}(k)|²} for example.

This can produce the following problem:

If

$${\sum }_{∀ k} {\sum }_{m = 1}^{{M}_{T}} {\vert {p}_{k , m , x} \vert}^{2} \neq const for all$$

$$x = 1 , … , D$$

the power of the channel estimation sequence fluctuates depending on the above-mentioned terms. The disadvantage of this is that the available power will not be used in the optimum way for channel estimation. This problem can be resolved by undertaking a permutation of the column vectors of [Pₖ], so that the width of fluctuation or variance of the power values

$$Px = {\sum }_{∀ k} {\sum }_{m = 1}^{{M}_{T}} {\vert {p}_{k , m , x} \vert}^{2}$$

over all x=1, . . . , D is minimized, taking into account the relationship pk,m,x=0 for x>Dk.

### EXAMPLE

All columns of [Pₖ] or their column vectors are first sorted in accordance with their size for all subcarriers k, so that

$${\sum }_{m = 1}^{{M}_{T}} {\vert {p}_{k , m , x} \vert}^{2} \geq {\sum }_{m = 1}^{{M}_{T}} {\vert {p}_{k , m , z} \vert}^{2} for z > x$$

applies. Subsequently these h column vectors are subjected to a random permutation in accordance with the specification P_{k,x}→P_{k,(x+k)modD}_{ₖ}.

Alternatively or additionally a signaling sequence of the signaling sections SI can also be defined for the respective antennas in order to implement a suitable MIMO transmission system.

In accordance with FIG. 5 the signaling section SI contains information about the physical processing of the data sequence, i.e. for example the number of the data streams per subcarrier k as well as their coding and modulation, the length of the data packet, etc. Depending on the type of physical processing the scope of this information varies, so that in the general case the underlying assumption is that more than one OFDM symbol (described in FIG. 5 by the parameter V) will be necessary for its transmission.

To avoid any overhead, the length of the signaling field SI should be matched adaptively to the scope of the information, a fact that can be indicated in the first OFDM symbol for example.

So that the information in the receiver can in its turn be correctly extracted, it must be encoded in a predefined manner, with the type of coding having to be as robust as possible because of the sensitivity of this information, i.e. fault-tolerant. This implies that the transmission should where possible be undertaken in diversity mode and not in multiplexing. So that the channel estimation preserves its validity, the same information is transmitted on all parallel data streams. This results in the signaling sequence am(n) comprising a concatenation of the OFDM symbols am,x(n) in accordance with
aₘ(n)=g_{m,1}(n)a_{m,1}(n)g_{m,2}(n)a_{m,2}(n) . . . g_{m,V}(n)a_{m,V}(n)
with

$$\begin{matrix}{a}_{m , x} ( n ) = {DFT}^{- 1} \{ {A}_{m , x} ( k ) \} und {A}_{m , x} ( k ) \\ = {I}_{x}^{sig} ( k ) \cdot {\sum }_{d = 1}^{{D}_{k}} {p}_{k , m , d} n \\ = 1 , … , N\end{matrix}$$

as well as

the typical OFDM guard interval sequence
g_{m,x}(n)=a_{m,x}(n+N−N_{G}) n=1, . . . , N_{G}.

The following equation then applies to the data sequence in the data field DA

$${d}_{m , x} ( n ) = {DFT}^{- 1} \{ {D}_{m , x} ( k ) \} mit {D}_{m , x} ( k ) = {\sum }_{d = 1}^{{D}_{k}} {p}_{k , m , d} \cdot {I}_{d , x} ( k ) ,$$

with Id,x(k) representing in this case the data symbol or the information which is transmitted on the dth spatial data stream of the kth subcarrier of the xth OFDM payload data symbols, i.e. on the spatial, temporal and spectral resource element.

Although in accordance with FIG. 5 the signaling structure SI is arranged in the time area between a user data structure DA and the channel estimation section KA of the preamble structure PS, the signaling structure can also be embodied in an alternative way.

Case 2:

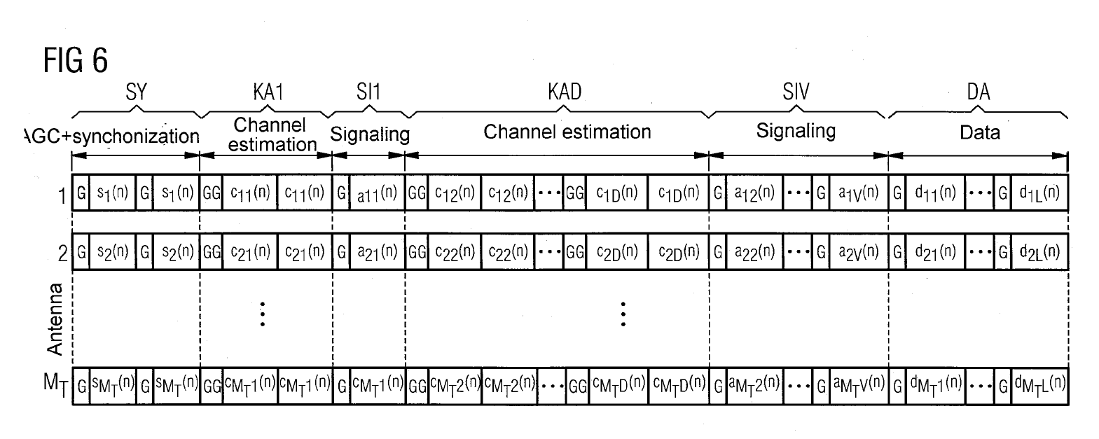

For case 2, in which SISO stations must also be able to evaluate the signaling field or the signaling structure SI, the preamble structure and signaling structure depicted in FIG. 6 in accordance with a second exemplary embodiment is proposed. The same reference symbols indicate the same or corresponding data sequences and such sequences are thus not described again.

In accordance with FIG. 6 an alternative preamble structure or signaling structure is proposed, with the channel estimation section I<A with a channel estimation sequence cm(n) being divided into a first part channel estimation section KA1 and a second part channel estimation section KAD with the part channel estimation sequences cm1(n) and also cm2(n) and the signaling section SI being divided into a first part signaling section SI1 and a second part signaling section SIV with the part signaling sequences am1(n) as well as am2(n) and being combined together again in the chronological sequence first part channel estimation section KA1, first part signaling section SI1, second part channel estimation section KAD and second part signaling section SIV. In this signaling section the first part signaling sequence is formed in accordance with
aₘ¹(n)=g_{m,1}(n)a_{m,1}(n)g_{m,2}(n)a_{m,2}(n) . . . g_{m,V′}(n)a_{m,V′}(n)

and the second part signaling sequence in accordance with
aₘ²(n)=g_{m,V′+1}(n)a_{m,V′+1}(n)g_{m,V′+2}(n)a_{m,V′+2}(n) . . . g_{m,V}(n)a_{m,V}(n)
with

$$\begin{matrix}{a}_{m , x} ( n ) = {DFT}^{- 1} \{ {A}_{m , x} ( k ) \} and {A}_{m , x} ( k ) \\ = \{ \begin{matrix}{I}_{x}^{sig} ( k ) \cdot {p}_{k , m , 1} & for 1 \leq x \leq {V}^{′} \\ {I}_{x}^{sig} ( k ) \cdot {\sum }_{d = 1}^{{D}_{k}} {p}_{k , m , d} & for {V}^{′} < x \leq V\end{matrix}\end{matrix}$$

As well as the typical OFDM guard interval sequence
g_{m,x}(n)=a_{m,x}(n+N−N_{G}) n=1, . . . , N_{G}.

The channel estimation sequences used correspond to the channel estimation sequences described above, with for example the first part channel estimation section KA1 being defined for x=1 and the second part channel estimation section KAD being defined for x=2 through D. By contrast with the exemplary embodiment in accordance with FIG. 5, with this second exemplary embodiment, a part of the signaling is moved forwards and typically corresponds to the signaling field of an existing SISO transmission system. In this way downwards or backwards compatibility to SISO transmission systems (802.11a systems) is obtained.

Optionally the complete signaling can be moved forwards. In this case the parameter D could be explicitly transferred as well as part of the signaling information, so that the number of the subsequent channel estimation sequences would be known a-priori.

The disclosure herein has been described here with reference to an OFDM transmission system in accordance with the IEEE 802.11 Standard. It is not restricted to this however and includes in the same manner alternate MIMO-OFDM transmission systems as well.

While the invention has been described with reference to one or more exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the appended claims.

1-19. (canceled)

20. A method for generating preamble structures and signaling structures for OFDM transmission systems having a plurality of antennas (1, . . . , M_{T}), comprising:
arranging the preamble structure for each antenna (1, . . . , M_{T}), such that the preamble structure comprises a synchronization section (SY) with a synchronization sequence and a channel estimation section (KA) with a channel estimation sequence;
arranging the signaling structure for each antenna, such that the signaling structure comprises at least one signaling section (SI) with a respective signaling sequence; and
determining the synchronization sequence sₘ(n) for a relevant antenna using one of the following two relationship established from the transmission system:
(1) sₘ(n)=DFT⁻¹{Sₘ(k)} with Sₘ(k)=S(k)·e^{jφ}^{_{k,m}} n−1, . . . , N,
and
$$\begin{matrix}{s}_{m} ( n ) = {DFT}^{- 1} \{ {S}_{m} ( k ) \} with {S}_{m} ( k ) = {\sum }_{d = 1}^{{D}_{k}} {p}_{k , m , d} \cdot \\ S ( k ) \cdot {ⅇ}^{{jφ}_{k , m , d}} n = 1 , … , N\end{matrix}$$
wherein:
S(k) representing a basic synchronization signal in the frequency range,
m=1, . . . , M_{T} is an antenna index,
M_{T} represents a number of transmit antennas,
n represents a sampling index,
k represents a subcarrier index,
N represents the number of the sample values per OFDM symbol,
d represents an index of the spatial data stream,
Dₖ represents the number of spatial data streams transmitted on the subcarrier, k, where p_{k,m,d}, an mth row, and dth column element of a matrix Pₖ, is used for spatial equalization of the payload data on the kth subcarrier,
φ_{k,m} represents a pseudo-random frequency-dependent and antenna-dependent phase rotation, and
φ_{k,m,d} represents a pseudo-random frequency-dependent, antenna-dependent and space-dependent phase rotation.

21. The method as claimed in claim 20, wherein the synchronization sequence sₘ(n) is prefixed by a guard interval (G) typical of OFDM.

22. The method as claimed in claim 20, wherein the synchronization sequence sₘ(n) is prefixed by a guard interval (G) with an inverted leading sign.

23. The method as claimed in claim 20, wherein the synchronization sequence sₘ(n) is repeated at least once periodically.

24. The method as claimed in claim 20, wherein the correlation of the phase values is as small as possible, corresponding to the relationship
$$E \{ {ⅇ}^{{jφ}_{k , m}} \cdot {ⅇ}^{- {jφ}_{k + Δ k , m + Δ m}} \} \to \{ \begin{matrix}1 & for Δ k = 0 ⋀ Δ m = 0 \\ 0 & else\end{matrix} ,$$
where E{ . . . } represents the expected value.

25. The method as claimed in claim 20, wherein the pseudo-random frequency-dependent and antenna-dependent phase rotation corresponds to the relationship:
$${φ}_{k , m} = \frac{2 π k ( m - 1 )}{{M}_{T}} .$$

26. The method as claimed in claim 20, wherein the basic synchronization signal satisfies the relationship:
$$\begin{matrix}{S ( k )}_{- 26 \text{:} 26} = \sqrt{\frac{13}{6}} \{ 0 , 0 , 1 + j , 0 , 0 , 0 , - 1 - j , 0 , 0 , 0 , 1 + \\ j , 0 , 0 , 0 , - 1 - j , 0 , 0 , 0 , - 1 - j , 0 , 0 , 0 , 1 + \\ j , 0 , 0 , 0 , 0 , 0 , 0 , 0 , - 1 - j , 0 , 0 , 0 , - 1 - \\ j , 0 , 0 , 0 , 1 + j , 0 , 0 , 0 , 1 + j , 0 , 0 , 0 , 1 + \\ j , 0 , 0 , 0 , 1 + j , 0 , 0 \}\end{matrix}$$

27. A method for generating preamble structures and signaling structures for a data packet in a MIMO-OFDM transmission system having a plurality of antennas (1, . . . , M_{T}), comprising:
arranging the preamble structure (PS) for each antenna (1, . . . , M_{T}) such that the preamble structure comprises a synchronization section (SY) with a synchronization sequence and a channel estimation section (KA) with a channel estimation sequence;
arranging the signaling structure for each antenna, such that the signaling structure comprises at least one signaling section (SI) with a signaling sequence in each case;
forming the channel estimation sequence cₘ(n) for the respective antennas from a concatenation of the OFDM symbols c_{m,x}(n) in accordance with
cₘ(n)=g_{m,1}(n)c_{m,1}(n)g_{m,2}(n)c_{m,2}(n) . . . g_{m,D}(n)c_{m,D}(n)
with
$${c}_{m , x} ( n ) = {DFT}^{- 1} \{ {C}_{m , x} ( k ) \} and$$
$${C}_{m , x} ( k ) = \{ \begin{matrix}{p}_{k , m , x} \cdot C ( k ) & x \leq {D}_{k} \\ 0 & {D}_{k} < x \leq D\end{matrix} n = 1 , … , N$$
wherein
C(k) represents a basic channel estimation signal in the frequency range,
m=1, . . . , M_{T} represents an antenna index,
M_{T} represents a number of the transmit antennas,
x=1, . . . , D represents an index of the spatial data stream,
n represents a sampling index,
D represents the maximum number of the spatial data streams over all subcarriers
$$D = {max}_{∀ k} {D}_{k} ,$$
g_{m,x}(n) represents a guard interval sequence as guard interval (G),
k represents a subcarrier index,
N represents the number of the sample values per OFDM symbol, where
p_{k,m,x} an mth row and xth column element of a Matrix Pₖ, is used for spatial equalization of the payload data on the kth subcarrier.

28. The method as claimed in claim 27, wherein the channel estimation sequence cₘ(n) is repeated at least once periodically.

29. The method as claimed in claim 27, wherein the channel estimation sequence cₘ(n) for the relevant antenna is formed from a concatenation of the OFDM symbols c_{m,x}(n) in accordance with
$$\begin{matrix}{c}_{m} ( n ) = {g}_{m , 1} ( n ) {\underbrace{{c}_{m , 1} ( n ) ⋯ {c}_{m , 1} ( n )}}_{j} {g}_{m , 2} ( n ) \\ {\underbrace{{c}_{m , 2} ( n ) ⋯ {c}_{m , 2} ( n )}}_{j} ⋯ {g}_{m , D} ( n ) \\ {\underbrace{{c}_{m , D} ( n ) ⋯ {c}_{m , D} ( n )}}_{j}\end{matrix}$$
with j representing the number of repetitions of the OFDM symbol c_{m,x}(n).

30. The method as claimed in claim 27, wherein a guard interval (G, GG) is formed from one of
(1) a single typical OFDM guard interval sequence
g_{m,x}(n)=c_{m,x}(n+N−N_{G}) n=1, . . . , N_{G}
and
(2) a double typical OFDM guard interval sequence
g_{m,x}(n)=c_{m,x}(n+N−2N_{G}) n=1, . . . , 2N_{G},
wherein N_{G} represents the number of sample values of the guard interval.

31. The method as claimed in claim 27, wherein the basic channel estimation signal satisfies the relationship
$$\begin{matrix}{C ( k )}_{- 26 \text{:} 26} = \{ 1 , 1 , - 1 , - 1 , 1 , 1 , - 1 , 1 , \\ - 1 , 1 , 1 , 1 , 1 , 1 , 1 , - 1 , - 1 , 1 , 1 , \\ - 1 , 1 , - 1 , 1 , 1 , 1 , 1 , 0 , 1 , - 1 , - 1 , 1 , 1 , \\ - 1 , 1 , - 1 , 1 , - 1 , - 1 , - 1 , - 1 , - 1 , 1 , 1 , - 1 , \\ - 1 , 1 , - 1 , 1 , - 1 , 1 , 1 , 1 , 1 \}\end{matrix}$$

32. The method as claimed in claim 27, wherein the signaling section (SI) is arranged in the time area between a payload data structure (DA) and the channel estimation section (KA), wherein the signaling section (SI) contains a signaling sequence aₘ(n) for the relevant antenna, which is formed from a concatenation of the OFDM symbols a_{m,x}(n) according to
aₘ(n)=g_{m,1}(n)a_{m,1}(n)g_{m,2}(n)a_{m,2}(n) . . . g_{m,V}(n)a_{m,V}(n)
with
a_{m,x}(n)=DFT⁻¹{A_{m,x}(k)} and
$${A}_{m , x} ( k ) = {I}_{x}^{sig} ( k ) \cdot {\sum }_{d = 1}^{{D}_{k}} {p}_{k , m , d} \qquad n = 1 , … , N$$
as well as the typical OFDM guard interval sequence
g_{m,x}(n)=a_{m,x}(n+N−N_{G}) n=1, . . . , N_{G},
where A_{m,x}(k) represents an xth signaling signal in the frequency range which will be transmitted over the mth antenna, and Iₓ^{sig}(k) represents signaling information which will be transmitted on the kth subcarrier of the xth OFDM signaling symbol.

33. The method as claimed in claim 27, wherein with the channel estimation section (KA) with a channel estimation sequence cₘ(n) being divided into a first part channel estimation section (KA1) and a second part channel estimation section (KAD) with the part channel estimation sequences cₘ¹(n) and also cₘ²(n), and the signaling section (SI) being divided into a first part signaling section (SI1) and a second part signaling section (SIV) with the part signaling sequences aₘ¹(n) and also aₘ²(n), and being combined together again in the chronological sequence first part channel estimation section (KA1), first part signaling section (SI1), second part channel estimation section (KAD) and second part signaling section (SIV), the first and second part channel estimation sequence being formed either in accordance with one of the following:
cₘ¹(n)=g_{m,1}(n)c_{m,1}(n)
cₘ²(n)=g_{m,2}(n)c_{m,2}(n) . . . g_{m,D}(n)c_{m,D}(n)
and
$${c}_{m}^{1} ( n ) = {g}_{m , 1} ( n ) {\underbrace{{c}_{m , 1} ( n ) ⋯ {c}_{m , 1} ( n )}}_{j}$$
$${c}_{m}^{2} ( n ) = {g}_{m , 2} ( n ) {\underbrace{{c}_{m , 2} ( n ) ⋯ {c}_{m , 2} ( n )}}_{j} ⋯ {g}_{m , D} ( n ) {\underbrace{{c}_{m , D} ( n ) ⋯ {c}_{m , D} ( n )}}_{j}$$
using a single or double typical OFDM guard interval, and with the first part signaling sequence being formed in accordance with
aₘ¹(n)=g_{m,1}(n)a_{m,1}(n)g_{m,2}(n)a_{m,2}(n) . . . g_{m,V′}(n)a_{m,V′}(n)
and the second part signaling sequence being formed in accordance with
aₘ²(n)=g_{m,V′+1}(n)a_{m,V′+1}(n)g_{m,V′+2}(n)a_{m,V′+2}(n) . . . g_{m,V}(n)a_{m,V}(n)
with
$${a}_{m , x} ( n ) = {DFT}^{- 1} \{ {A}_{m , x} ( k ) \}$$
$$and$$
$${A}_{m , x} ( k ) = \{ \begin{matrix}{I}_{x}^{sig} ( k ) \cdot {p}_{k , m , 1} & für & 1 \leq x \leq {V}^{′} \\ {I}_{x}^{sig} ( k ) \cdot {\sum }_{d = 1}^{{D}_{k}} {p}_{k , m , d} & für & {V}^{′} < x \leq V '\end{matrix} n = 1 , … , N$$
as well as the typical OFDM guard interval sequence
g_{m,x}(n)=a_{m,x}(n+N−N_{G}) n=1, . . . , N_{G}
with j representing the number of repetitions of the OFDM symbols c_{m,x}(n), A_{m,x}(k) an xth signaling signal in the frequency range which will be transmitted via the mth antenna, and Iₓ^{sig}(k) signaling information which will be transmitted on the kth subcarrier of the xth OFDM signaling symbol, and with V′ designating a number of OFDM symbols which is required for transmission of part signaling information, and V designating a number of OFDM symbols which is required for transmission of complete signaling information.

34. The method as claimed in claim 27, wherein the synchronization section (SY) is prefixed with a synchronization sequence sₘ(n) to form a common preamble structure and signaling structure (PS).

35. The method as claimed in claim 27, wherein the column vectors P_{k,x}, x=1, . . . , Dₖ, of the matrix Pₖ are sorted so that the variance of the power values
$${P}_{x} = {\sum }_{∀ k} {\sum }_{m = 1}^{{M}_{T}} {\vert {p}_{k , m , x} \vert}^{2} \qquad x = 1 , … , D$$
becomes as small as possible, taking into account the relationship p_{k,m,x}=0 for x>Dₖ.

36. The method as claimed in claim 27, wherein, for each subcarrier k, the column vectors P_{k,x}, with x=1, . . . , Dₖ, of the spatial equalization matrix Pₖ are sorted in a first step in accordance with their size, so that
$${\sum }_{m = 1}^{{M}_{T}} {\vert {p}_{k , m , x} \vert}^{2} \geq {\sum }_{m = 1}^{{M}_{T}} {\vert {p}_{k , m , z} \vert}^{2} \qquad for \qquad z > x$$
is satisfied, and in a second step are subjected to a random permutation.

37. The method as claimed in claim 36, wherein the permutation of the column vectors is undertaken in accordance with the specification
P_{k,x}→P_{k,(x+k)modD}_{ₖ}.

38. The method as claimed in claim 27, wherein the OFDM transmission system is designed in accordance with the IEEE 802.11 standard.

39. The method as claimed in claim 20, wherein the OFDM transmission system is designed in accordance with the IEEE 802.11 standard.
